(19) United States
(12) Patent Application Publication
(10) Pub. No.: US 2023/0096595 A1
(43) Pub. Date: Mar. 30, 2023

(54) POLYOXOMOLYBDATE MATERIAL AND PREPARATION METHOD AND USE THEREOF, SOLAR CELL, AND ORGANIC LIGHT-EMITTING DIODE

(71) Applicant: Jilin University, Changchun (CN)

(72) Inventors: Fenghong Li, Changchun (CN); Lixin Wu, Changchun (CN); Jing Qiu, Changchun (CN); Yan Wang, Changchun (CN); Guofeng Wan, Changchun (CN)

(21) Appl. No.: 17/870,281

(22) Filed: Jul. 21, 2022

(30) Foreign Application Priority Data
Sep. 13, 2021 (CN) 202111068806.0

(51) Int. Cl. C07F 11/00; H01L 51/44

(52) U.S. Cl. CPC C07F 11/00; H01L 51/441

(57) ABSTRACT

The present disclosure provides a polyoxomolybdate material and a preparation method and use thereof, a solar cell, and an organic light-emitting diode (OLED), and belongs to the technical field of optoelectronic devices. An organic solar cell (OSC) with the polyoxomolybdate material of the present disclosure as an electrode interface material has an open-circuit voltage of 0.810 V to 0.860 V, a short-circuit current density of 24.50 mA/cm² to 26.10 mA/cm², a fill factor of 68.7% to 78.8%, and a power conversion efficiency (PCE) of 14.21% to 17.42%. An OLED with the polyoxomolybdate material of the present disclosure has a turn-on voltage of 2.3 V to 3.5 V, a maximum brightness of 14,330 cd/m² to 43,430 cd/m², a current efficiency of 7.00 cd/A to 15.00 cd/A, and a power efficiency of 3.50 lm/W to 13.00 lm/W, and exhibits prominent LED performance.

### CROSS REFERENCE TO RELATED APPLICATION

This patent application claims the benefit and priority of Chinese Patent Application No. 202111068806.0, filed on Sep. 13, 2021, the disclosure of which is incorporated by reference herein in its entirety as part of the present application.

### BACKGROUND

### Related Field

The present disclosure relates to the technical field of optoelectronic devices, and in particular to a polyoxomolybdate material and a preparation method and use thereof; a solar cell, and an organic light-emitting diode (OLED).

### Related Art

Organic solar cells (OSCs) have become a hot topic extensively investigated and potential candidates for powering wearable devices, architectural glass, intelligent greenhouses, Internet of Things (IoT), etc due to their advantages of non-toxicity, low-cost, light weight, mechanical flexibility, semitransparency, solution processing and large-area roll-to-roll fabrication.

With the continuous development of non-fullerene acceptors, the power conversion efficiency (PCE) of OSCs has been significantly improved, and currently, the maximum PCE of OSCs has exceeded 19%. The use of an appropriate electrode interfacial layer is an effective strategy to enhance the performance of an OSC. A function of an electrode interfacial layer mainly includes effectively adjusting a work function of an electrode, reducing a carrier extraction barrier, and improving a contact between an electrode and an active layer. According to modified electrodes, electrode interfacial layers are usually divided into anode interfacial layers (AILs) and cathode interfacial layers (CILs). In an OSC with a conventional structure, AIL is usually made of poly(3,4-ethylenedioxythiophene):polystyrene sulfonate (PEDOT:PSS), but PEDOT:PSS itself is hydrophilic and acidic, which is not conducive to the long-tem stability of the OSC. Several common CILs such as PFN-Br (Yong Cui, Huifeng Yao, Jianqi Zhang, Kaihu Xian, Tao Zhang, Ling Hong, Yuming Wang, Ye Xu, Kangqiao Ma, Cunbin An, Chang He, Zhixiang Wei, Feng Gao, and Jianhui Hou. Single-Junction Organic Photovoltaic Cells with Approaching 18% Efficiency. Adv. Mater. 2020, 32, 1908205.), PDINO (Zhi-Guo Zhang, Boyuan Qi, Zhiwen Jin, Dan Chi, Zhe Qi, Yongfang Li and Jizheng Wang. Perylene diimides: a thickness-insensitive cathode interlayer for high performance polymer solar cells. Energy Environ. Sci. 2014, 7, 1966.), and PNDIT-F3N (Kui Jiang, Qingya Wei, Joshua Yuk Lin Lai, Zhengxing Peng, Ha Kyung Kim, Jun Yuan, Long Ye, Harald Ade, Yingping Zou, and He Yan. Alkyl Chain Tuning of Small Molecule Acceptors for Efficient Organic Solar Cells. Joule 2019, 3, 3020.) can make the OSCs have high efficiency, but have a high cost, and are not suitable for large-area industrial production of OSCs. In perovskite solar cells, CILs arc usually made of tin dioxide (SnO₂), bathocuproine (BCP), or the like. However, SnO₂ needs to be thermally annealed, and BCP has the problems of low electric conductivity and high price. Most of the CILs for OLEDs are fabricated through vacuum evaporation, which involves a complicated preparation process and a high cost. Therefore, the study of novel cathode interface materials is of great significance for the development of extended optoelectronic devices.

### BRIEF SUMMARY

The present disclosure is intended to provide a polyoxomolybdate material and a preparation method and use thereof, a solar cell, and an OLED. An optoelectronic device fabricated with the polyoxomolybdate material as an electrode interface material has excellent optoelectronic properties.

To achieve the above objective of the present disclosure, the present disclosure provides the following technical solutions.

The present disclosure provides a polyoxomolybdate material, with a composition shown in formula 1:

((CₙH₂ₙ₊₁)₄N)ₓ(NH₄)_{y}[Mo₇₂^{VI}Mo₆₀^{V}O₃₇₂(CH₃COO)₃₀(H₂O)₇₂] formula 1,

where n=4 to 12; x and y are each independently 1 to 42; and x+y≤42, x≠0, and y≠42.

Preferably, n=4, 6, 8, 10, or 12.

The present disclosure provides a preparation method of the polyoxomolybdate material according to the above technical solution, including the following steps:

mixing a NH₄-Mo₁₃₂ solution and an alkylammonium bromide solution, and obtaining the polyoxomolybdate material by an exchange reaction.

where the NH₄-Mo₁₃₂ has a structure shown in formula 2:

(NH₄)₄₂[Mo₇₂^{VI}Mo₆₀^{V}O₃₇₂(CH₃COO)₃₀(H₂O)₇₂](H₂O)₃₀₀(CH₃COONH₄)₁₀ formula 2; and

the alkylammonium bromide in the alkylammonium bromide solution has a structural formula of (CₙH₂ₙ₊₁)₄NBr, where n=4 to 12.

Preferably, a molar ratio of the NH₄-Mo₁₃₂ in the NH₄-Mo₁₃₂ solution to the alkylammonium bromide in the alkylammonium bromide solution may be 1:(1-42).

Preferably, the exchange reaction may be conducted at room temperature for 12 h to 24 h.

The present disclosure provides use of the polyoxomolybdate material according to the above technical solution or a polyoxomolybdate material prepared by the preparation method according to the above technical solution as a CIL material in a field of optoelectronic devices.

The present disclosure provides an OSC, including an anode, an AIL, an active layer, a CIL, and a cathode that are stacked sequentially, where a material of the CIL is the polyoxomolybdate material according to the above technical solution or a polyoxomolybdate material prepared by the preparation method according to the above technical solution.

The present disclosure provides an organic-inorganic hybrid perovskite solar cell (PSC), including an anode, an AIL, a photoactive layer, an electron transport layer (ETL), a CIL, and a cathode that are stacked sequentially, where a material of the CIL is the polyoxomolybdate material according to the above technical solution or a polyoxomolybdate material prepared by the preparation method according to the above technical solution.

The present disclosure provides an OLED, including an anode, a hole transport layer (HTL), a light-emitting layer, an ETL, and a cathode that arc stacked sequentially, where a material of the ETL is the polyoxomolybdate material according to the above technical solution or a polyoxomolybdate material prepared by the preparation method according to the above technical solution.

The present disclosure provides a polyoxomolybdate material, which is a kepelerate-type isopolymolybdate cluster. The kepelerate-type polyoxomolybdate material has a surface-porous hollow structure with a diameter of about 2.9 nm, where the structure is definite and controllable and an energy level is adjustable. The polyoxomolybdate material includes both Mo^{V} and Mo_{VI}, and thus can gain electrons and lose electrons, resulting in excellent redox characteristics. The excellent redox characteristics can promote the transport of carriers, and is favorable for the improvement of device performance. Therefore, the polyoxomolybdate material can be used as a CIL material to improve the performance of an optoelectronic device.

The present disclosure provides a preparation method of the polyoxomolybdate material, which involves simple synthesis steps, environmentally-friendly solvents, and cheap raw materials.

The present disclosure applies {Mo₁₃₂} materials in the fields of OSCs, perovskite solar cells, and OLEDs for the first time. An OSC with the polyoxomolybdate material of the present disclosure as an electrode interface material has an open-circuit voltage of 0.810 V to 0.860 V, a short-circuit current density of 24.50 mA/cm² to 26.10 mA/cm², a fill factor of 68.7% to 78.8%, and a PCE of 14.21% to 17.42%. A perovskite solar cell with the polyoxomolybdate material of the present disclosure as an electrode interface material has an open-circuit voltage of 1.05 V to 1.10 V, a short-circuit current density of 21.00 mA/cm² to 22.00 mA/cm², a filling factor of 75.0% to 77.0%, and a PCE of 17.00% to 18.50%, and exhibits excellent solar cell performance. An OLED with the polyoxomolybdate material of the present disclosure as an electrode interface material has a turn-on voltage of 2.3 V to 3.5 V, a maximum brightness of 14,330 cd/m² to 43,430 cd/m², a current efficiency of 7.00 cd/A to 15.00 cd/A, and a power efficiency of 3.50 lm/W to 13.00 lm/W, and exhibits prominent LED performance.

### BRIEF DESCRIPTION OF THE DRAWINGS

FIG. 1 shows a current density-voltage curve of the OSC fabricated in Application Example 1;

FIG. 2 shows a current density-voltage curve of the OSC fabricated in Application Example 2;

FIG. 3 shows a current density-voltage curve of the perovskite solar cell fabricated in Application Example 3;

FIG. 4 shows efficiency-current density curves of the OLED fabricated in Application Example 4; and

FIG. 5 shows efficiency-current density curves of the OLED fabricated in Application Example 5.

### DETAILED DESCRIPTION OF THE EMBODIMENTS

The present disclosure provides a polyoxomolybdate material, with a composition shown in formula 1:

((CₙH₂ₙ₊₁)₄N)ₓ(NH₄)_{y}[Mo₇₂^{VI}Mo₆₀^{V}O₃₇₂(CH₃COO)₃₀(H₂O)₇₂] formula 1,

where n=4 to 12; x and y are each independently 1 to 42; and x+y≤42, x≠0, and y≠42.

In the present disclosure, the n may preferably be 4, 6, 8, 10, or 12; and the x+y may preferably be 42.

The polyoxomolybdate material provided by the present disclosure relics on an electrostatic interaction between an organic part (alkyl quaternary ammonium cation) and an inorganic part (polyoxometalate anion) to exist stably.

In a specific embodiment of the present disclosure, the polyoxomolybdate material may specifically be:

((C₄H₉)₄N)₁₅(NH₄)₂₇[Mo₇₂^{VI}Mo₆₀^{V}O₃₇₂(CH₃COO)₃₀(H₂O)₇₂](abbreviated as (C₄)₁₅-Mo₁₃₂),

((C₆H₁₃)₄N)₂₀(NH₄)₂₂[Mo₇₂^{VI}Mo₆₀^{V}O₃₇₂(CH₃COO)₃₀(H₂O)₇₂](abbreviated as (C₆)₂₀-Mo₁₃₂),

((C₆H₁₃)₄N)₂₁(NH₄)₂₁[Mo₇₂^{VI}Mo₆₀^{V}O₃₇₂(CH₃COO)₃₀(H₂O)₇₂](abbreviated as (C₆)₂₁-Mo₁₃₂),

((C₈H₁₇)₄N)₁₁(NH₄)₃₁[Mo₇₂^{VI}Mo₆₀^{V}O₃₇₂(CH₃COO)₃₀(H₂O)₇₂](abbreviated as (C₈)₁₁-Mo₁₃₂),

((C₈H₁₇)₄N)₁₉(NH₄)₂₃[Mo₇₂^{VI}Mo₆₀^{V}O₃₇₂(CH₃COO)₃₀(H₂O)₇₂](abbreviated as (C₈)₁₉-Mo₁₃₂),

((C₈H₁₇)₄N)₃₁(NH₄)₄[Mo₇₂^{VI}Mo₆₀^{V}O₃₇₂(CH₃COO)₃₀(H₂O)₇₂](abbreviated as (C₈)₃₁-Mo₁₃₂),

((C₁₀H₂₁)₄N)₂₀(NH₄)₂₂[Mo₇₂^{VI}Mo₆₀^{V}O₃₇₂(CH₃COO)₃₀(H₂O)₇₂](abbreviated as (C₁₀)₂₀-Mo₁₃₂),

The present disclosure provides a preparation method of the polyoxomolybdate material according to the above technical solution, including the following steps:

mixing a NH₄-Mo₁₃₂ solution and an alkylammonium bromide solution, and obtaining the polyoxomolybdate material by an exchange reaction.,

where the NH₄-Mo₁₃₂ has a structure shown in formula 2:

(NH₄)₄₂[Mo₇₂^{VI}Mo₆₀^{V}O₃₇₂(CH₃COO)₃₀(H₂O)₇₂](H₂O)₃₀₀(CH₃COONH₄)₁₀ formula 2; and

the alkylammonium bromide in the alkylammonium bromide solution has a structural formula of (CₙH₂ₙ₊₁)₄NBr, where n=4 to 12.

In the present disclosure, unless otherwise specified, all raw materials required for preparation are commercially available products well known to those skilled in the art.

In the present disclosure, a preparation process of NH₄-Mo₁₃₂ in the NH₄-Mo₁₃₂ solution may preferably be as follows: N₂H₄ (H₂SO₄) (0.8 g, 4.5 mmol) is added to 250 mL of an aqueous solution with (NH₄)₆[Mo₇O₂₄] (H₂O)₄ (5.6 g, 4.5 mmol) and CH₃COONH₄ (12.5 g, 162.2 mmol), a resulting mixed solution is stirred for 10 min such that the mixed solution turns blue-green, and then a CH₃COOH (83 mL, mass fraction: 50%) solution is added to obtain a green solution; the green solution is placed in a 500 mL open flask, and stirred at 20° C. in a fume hood such that the green solution slowly turns dark-brown. A flask containing the dark brown solution is covered with fresh-keeping film, and is allowed to stand for four days for crystal growth. A resulting solution is filtered to obtain a red-brown crystal. Then the obtained crystal is rinsed with each of 90% ethanol and diethyl ether, and then air-dried to obtain the NH₄-Mo₁₃₂.

In the present disclosure, a solvent used for the NH₄-Mo₁₃₂ solution may preferably include water, ethanol-water, or acetonitrile-water; a volume ratio of ethanol to water in the ethanol-water may preferably be (1-4):1; and a volume ratio of acetonitrile to water in the acetonitrile-water may preferably be (1-4):1.

In the present disclosure, a solvent used for the alkylammonium bromide solution may preferably be the same as the solvent used for the NH₄-Mo₁₃₂ solution.

In the present disclosure, in the alkylammonium bromide, n may preferably be 4, 6, 8, 10, or 12. The present disclosure has no special limitations on a source of the (CₙH₂ₙ₊₁)₄NBr and a commercially available product well known to those skilled in the art or a product prepared by a preparation method well known in the art may be adopted.

In the present disclosure, a charge molar ratio of the NH₄-Mo₁₃₂ in the NH₄-Mo₁₃₂ solution to the alkylammonium bromide in the alkylammonium bromide solution may be preferably 1:(1-42) and more preferably 1:(1-40); and the charge mole refers to a product of a charge number of a raw material and a corresponding mole number. The present disclosure has no special limitations on concentrations of the NH₄-Mo₁₃₂ solution and the alkylammonium bromide solution and a volume ratio of the two, provided that a reaction is allowed according to the above molar ratio.

The present disclosure has no special limitations on a mixing process of the NH₄-Mo₁₃₂ solution and the alkylammonium bromide solution, and the materials can be thoroughly mixed according to a process well known in the art. In an embodiment of the present disclosure, the alkylammonium bromide solution may be added dropwise to the NH₄-Mo₁₃₂ solution; and the present disclosure has no special limitations on a rate of the dropwise addition, provided that it does not cause liquid splashing.

In the present disclosure, the exchange reaction may be conducted preferably at room temperature preferably for 24 h; and the exchange reaction may be conducted preferably under stirring. The present disclosure has no special limitations on a process of the stirring, and a stirring process well known in the art that makes the reaction proceed smoothly may be adopted. During the exchange reaction, the alkyl quaternary ammonium cation is combined with the Mo₁₃₂ anion to produce surfactant-encapsulated Mo₁₃₂, namely, a structure shown in formula 1.

In the present disclosure, after the exchange reaction is completed, a resulting system may preferably be separated (or ultrasonically vibrated for 1 min and then separated), washed and dried to obtain the polyoxomolybdate material. In the present disclosure, a method for the separation may preferably be filtration or centrifugation; a reagent used for the washing may be preferably a polar reagent and more preferably water; and a method for the drying may preferably be vacuum-drying, and the drying may be conducted preferably for 12 h at a temperature preferably of 40° C. and a vacuum degree preferably of 0.09 MPa.

The present disclosure provides use of the polyoxomolybdate material according to the above technical solution or a polyoxomolybdate material prepared by the preparation method according to the above technical solution as a CIL material in a field of optoelectronic devices.

The present disclosure provides an OSC, including an anode, an AIL, an active layer, a CIL, and a cathode that are stacked sequentially, where a material of the CIL is the polyoxomolybdate material according to the above technical solution or a polyoxomolybdate material prepared by the preparation method according to the above technical solution.

The OSC provided by the present disclosure includes an anode. The anode may be preferably indium tin oxide (ITO), and the ITO may preferably be treated under UV-ozone for 30 min before use. A thickness of the anode may be preferably 100 nm to 200 nm, more preferably 110 nm to 150 nm, and further more preferably 135 nm.

In the present disclosure, the anode may be preferably attached to a substrate, and the substrate may be preferably a glass substrate. The present disclosure has no special limitations on a thickness of the substrate, and a thickness well known in the art may be adopted.

The OSC provided by the present disclosure includes an AIL stacked on a side surface of the anode. In the present disclosure, a material of the AIL may preferably be NH₄-Mo₁₃₂ or PEDOT:PSS. When the material of the AIL is PEDOT:PSS, a thickness of the AIL may be preferably 10 nm to 40 nm, more preferably 25 nm to 35 nm, and further more preferably 30 nm. When the material of the AIL is NH₄-Mo₁₃₂, a thickness of the AIL may be preferably 5 nm to 10 nm and more preferably 7 nm. The present disclosure has no special limitations on a source of the PEDOT:PSS, and a commercially-available product well known in the art may be adopted.

The OSC provided by the present disclosure includes an active layer stacked on a surface of the AIL. In the present disclosure, the active layer may be preferably a mixture of a donor material and an acceptor material; the donor material may be preferably one or two selected from the group consisting of PTB7-Th, PTB7, PCDTBT, PBDB-T, and PM6; and the acceptor material may be preferably one or two selected from the group consisting of PC₆₁BM, PC₇₁BM, ITIC, IEICO-4F, IT-4F, Y6, BTP-BO-4Cl, and L8-BO. In the present disclosure, a mass ratio of the donor material to the acceptor material may be preferably 1:(0.8 -2) and more preferably 1:(1.2-1.5).

In the present disclosure, the active layer may be more preferably a mixture of one donor material and one acceptor material, a mixture of one donor material and two acceptor materials, or a mixture of two donor materials and one acceptor material. When the active layer is a mixture of one donor material and two acceptor materials, on the premise that a mass ratio of the donor material to the acceptor materials is 1:(0.8-2), the present disclosure has no special limitations on a ratio of the two receptor materials, and any ratio may be adopted. When the active layer is a mixture of two donor materials and one acceptor material, the present disclosure has no special limitations on a ratio of the two donor materials, and any ratio may be adopted.

In the present disclosure, structural formulas of materials in the active layer are as follows:

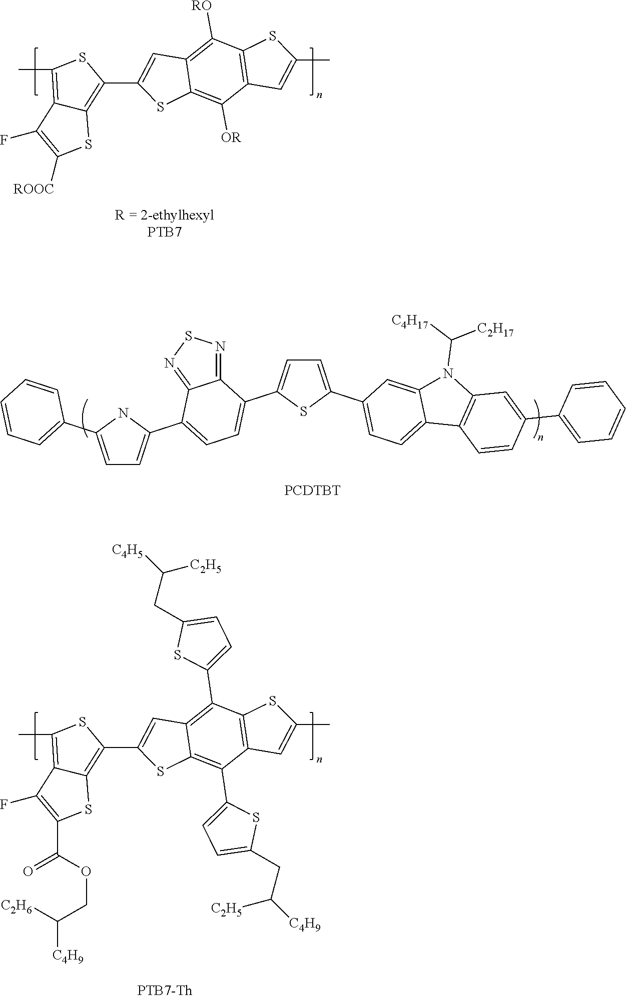

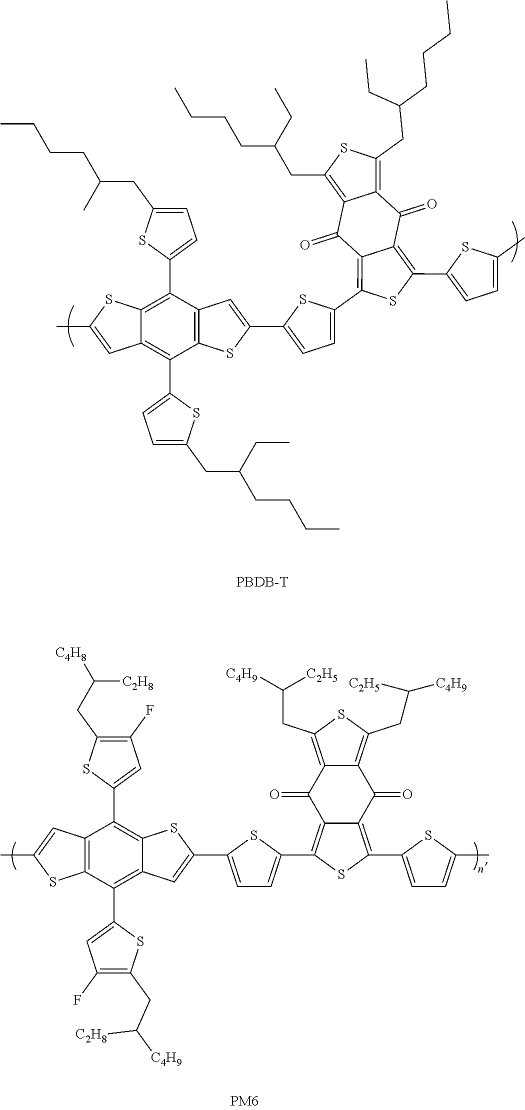

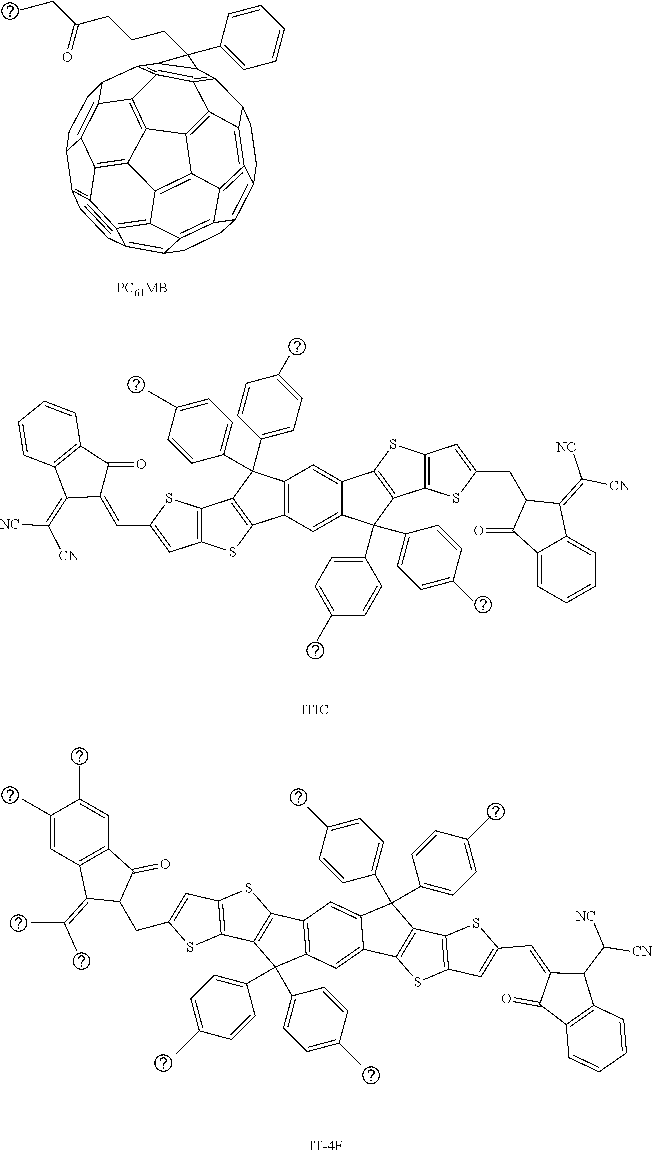

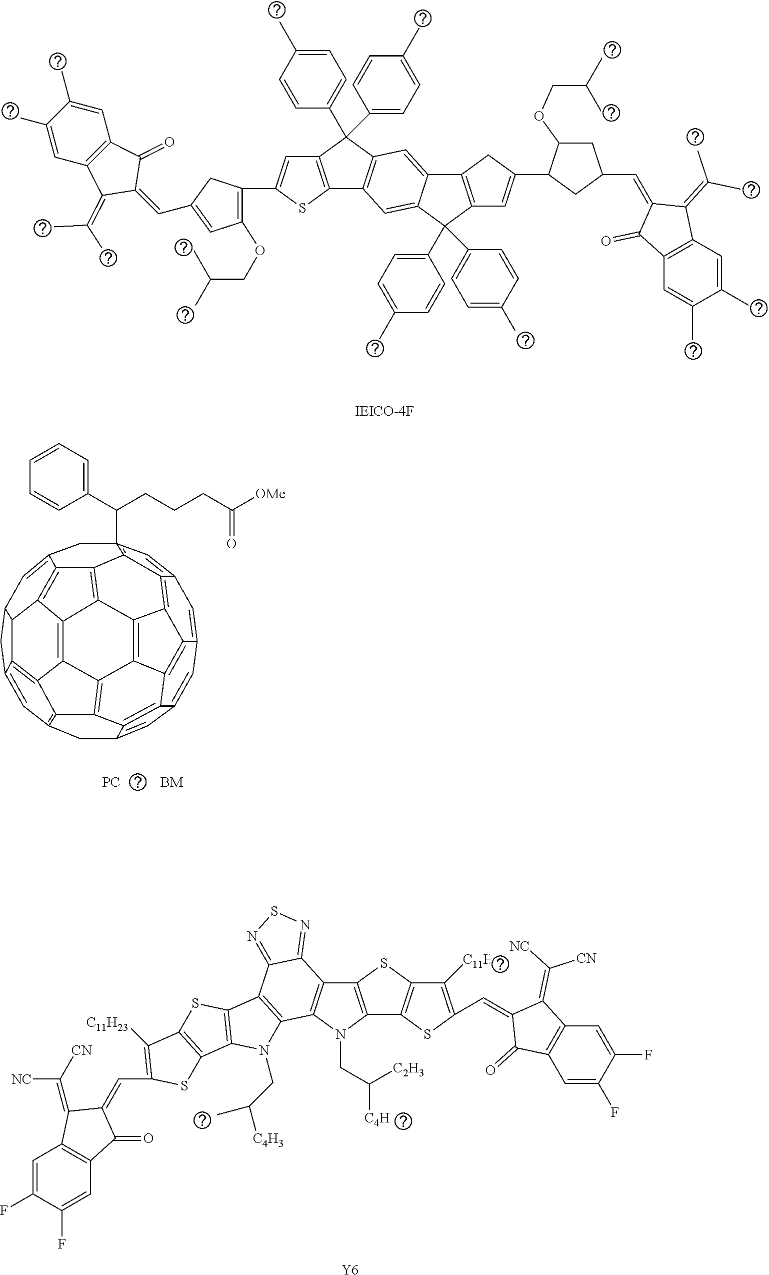

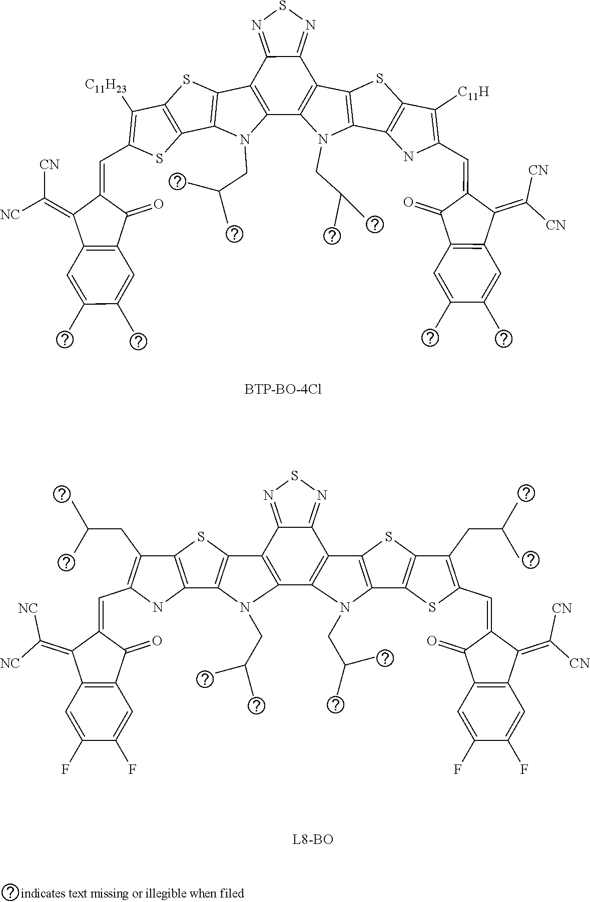

In the present disclosure, a thickness of the active layer may be preferably 80 nm to 120 nm, more preferably 90 nm to 110 nm, and most preferably 100 nm.

The OSC provided by the present disclosure includes a CIL stacked on a surface of the active layer. In the present disclosure, the CIL may be preferably the polyoxomolybdate material with a structure of formula 1 described in the above technical solution.

In the present disclosure, a thickness of the CIL may be preferably 0.5 nm to 20 nm, more preferably 4 nm to 15 nm, and most preferably 5 nm.

The OSC provided by the present disclosure includes a cathode stacked on a surface of the CIL. In the present disclosure, the cathode may preferably be silver, aluminum, copper, or gold; and a thickness of the cathode may be preferably 80 nm to 120 nm, more preferably 90 nm to 110 nm, and most preferably 100 nm.

In the present disclosure, a fabrication method of the OSC may preferably include the following steps:

an AIL material solution is coated on a surface of an anode to form an AIL on the surface of the anode;

an active layer solution is coated on a surface of the AIL, and a solvent is volatilized to form an active layer on the surface of the AIL;

an organic CIL material solution is coated on a surface of the active layer to form a CIL on the surface of the active layer; and

a cathode is evaporated on a surface of the CIL to obtain the OSC.

In the present disclosure, an AM material solution may be coated on a surface of an anode to form an AIL on the surface of the anode. In the present disclosure, the anode may be preferably attached to a substrate. In the present disclosure, the anode may be preferably evaporated on a surface of the substrate, such that the anode is attached to the substrate. The present disclosure has no special limitations on conditions of the evaporation, and evaporation conditions well known in the art may be adopted. In the present disclosure, a thickness of the anode evaporation corresponds to the thickness of the anode in the above technical solution.

In the present disclosure, when the AIL material is NH₄-Mo₁₃₂, a solvent used for the AIL material solution may be preferably methanol; and the AIL material solution may have a concentration of preferably 0.25 mg/mL to 2 mg/mL and more preferably 1 mg/mL to 1.25 mg/mL. In the present disclosure, a method for the coating may be preferably spin-coating, and the spin-coating may be conducted at a speed of preferably 1,900 r/min to 2,100 r/min and more preferably 2,000 r/min. The present disclosure has no specific limitations on a time of the coating, and the coating time can be adjusted according to a coating thickness. In the present disclosure, a coating thickness of the AIL material corresponds to the thickness of the AIL.

In the present disclosure, when me AIL material is PEDOT:PSS, the PEDOT:PSS may be preferably a PEDOT:PSS aqueous solution with model No. Clevios PVP Al 4083 purchased from Heraeus, Germany. In the present disclosure, the PEDOT:PSS aqueous solution may be preferably filtered through a 0.45 μm filter membrane before use. In the present disclosure, a method for the coating may be preferably spin-coating, and the spin-coating may be conducted at a speed of preferably 3,000 r/min to 4,000 r/min and more preferably 3,500 r/min.

When the AIL material is PEDOT:PSS, after the coating is completed, the present disclosure may preferably conduct an annealing treatment. When the AIL material is NH₄-Mo₁₃₂, after the coating is completed, the present disclosure may preferably allow standing for 2 min to 5 min in a nitrogen glove box to make a solvent volatilized. In the present disclosure, the annealing treatment may be conducted at preferably 100° C. to 120° C. and more preferably 110° C.; and the annealing treatment may be conducted for preferably 20 min to 30 min and more preferably 30 min. The present disclosure utilizes the annealing treatment to remove moisture in a film, thereby facilitating the stability of the OSC device.

In the present disclosure, after the AIL is formed, an active layer solution may be preferably coated on a surface of the AIL, and then a solvent may be volatilized to form an active layer on the surface of the AIL. The present disclosure has no special limitations on a type of the solvent used for the active layer solution, and according to a specific composition of the active layer, a corresponding solvent well known in the art may be adopted. In the present disclosure, the active layer solution may have a concentration of preferably 10 mg/mL to 30 mg/mL and more preferably 16 mg/mL to 25 mg/mL. In addition, the present disclosure may preferably select and use an additive based on the composition of the active layer and actual needs. The present disclosure has no special limitations on a type, use method, and an amount of the additive, and the additive can be selected and used according to a method well known in the art. In an application example of the present disclosure, the active layer may be PM6:Y6, and the additive may be chloronaphthalene.

In the present disclosure, a method for the coating may be preferably spin-coating, and the spin-coating may be conducted at a speed of preferably 1,000 r/min to 3,000 r/min and more preferably 1,500 r/min to 2,500 r/min. The present disclosure has no specific limitations on a time of the coating, and the coating time can be adjusted according to a coating thickness. In the present disclosure, a coating thickness of the active layer solution corresponds to the thickness of the active layer.

In the present disclosure, the solvent may be volatilized preferably by an annealing treatment or placing overnight under vacuum conditions. When a proportion of the additive exceeds 0.5% of a total volume of the solvent and the additive, the present disclosure may preferably make the solvent volatilized by placing overnight under vacuum conditions. When the additive is not used or a proportion of the additive is 0.5% or less of a total volume of the solvent and the additive, the present disclosure may preferably make the solvent volatilized by an annealing treatment. In the present disclosure, the annealing treatment may be conducted at preferably 60° C. to 110° C. and more preferably 70° C. to 100° C. for preferably 10 min to 30 min. The annealing treatment of the present disclosure can change the crystallinity of the active layer to form a prominent phase separation structure, which facilitates the transport of carriers and increases the current.

In the present disclosure, after the active layer is formed, an organic CIL material solution may be coated on a surface of the active layer to form a CIL on the surface of the active layer. In the present disclosure, a solvent used for the organic CIL material solution may be preferably methanol; and the organic CIL material solution may have a concentration of preferably 0.25 mg/mL to 2 mg/mL, more preferably 0.5 mg/mL to 1 mg/mL, and further more preferably 0.5 mg/mL.

In the present disclosure, a method for the coating may be preferably spin-coating, and the spin-coating may be conducted at a speed of preferably 1,900 r/min to 2,100 r/min and more preferably 2,000 r/min. The present disclosure has no specific limitations on a time of the coating, and the coating time can be adjusted according to a coating thickness. In the present disclosure, a coating thickness of the organic CIL material solution corresponds to the thickness of the CIL.

In the present disclosure, after the CIL is formed, a cathode may be evaporated on a surface of the CIL to obtain the OSC. The present disclosure has no special limitations on a method of the evaporation, and an evaporation method well known in the art may be adopted. In the present disclosure, the evaporation may be conducted preferably with aluminum, silver, copper, or gold as a raw material; the evaporation may be conducted at a rate of preferably 0.5 Å/s to 1.5 Å/s, more preferably 0.7 Å/s to 1.3 Å/s, and most preferably 1 Å/s; the evaporation may be conducted under a vacuum degree of preferably (1.7-1.9)×10⁻⁴ Pa and more preferably 1.8×10⁻⁴ Pa; the evaporation may be conducted at a current of preferably 32 A to 40 A and more preferably 34 A to 37 A; and the evaporation may be conducted at a voltage of preferably 2 V to 4 V and more preferably 3.5 V to 4 V. The present disclosure has no special limitations on a form of the metal used for the evaporation, and commercially-available aluminum, silver, copper, and gold (powder, strip, sheet, or block) for evaporation well known in the art may be adopted.

The present disclosure provides a PSC, including an anode, an AIL, a photoactive layer, an ETL, a CIL, and a cathode that are stacked sequentially, where a material of the CIL is the polyoxomolybdate material according to the above technical solution or a polyoxomolybdate material prepared by the preparation method according to the above technical solution.

The PSC provided by the present disclosure includes an anode. In the present disclosure, the anode may preferably be ITO, and a thickness of the anode may be preferably 100 nm to 200 nm, more preferably 110 nm to 150 nm, and most preferably 135 nm.

In the present disclosure, the anode may be preferably attached to a substrate, and the substrate may be preferably a glass substrate. The present disclosure has no special limitations on a thickness of the substrate, and a thickness well known in the art may be adopted.

The PSC provided by the present disclosure includes an AIL stacked on a surface of the anode. In the present disclosure, a material of the AIL may preferably be NH₄-Mo₁₃₂ or poly[bis(4-phenyl)(2,4,6-trimethylphenyl)amine] (PTAA). The present disclosure has no special limitations on the PTAA, and a commercially-available product well known in the art may be adopted. In the present disclosure, a thickness of the AIL may be preferably 5 nm to 20 nm and more preferably 10 nm.

The PSC provided by the present disclosure includes a photoactive layer stacked on a surface of the AIL. In the present disclosure, a material of the photoactive layer may be preferably an ABX₃-type compound with a perovskite crystal structure, where A represents an organic cation, including a methylamine cation (MA⁺), a formamidine cation (FA⁺), or a monovalent metal cation, and the monovalent metal cation may preferably include a cesium cation (Cs⁺) or a rubidium cation (Rb⁺); B represents a divalent lead cation (Pb²⁺); and X represents a halogen anion, and the halogen anion may preferably include an iodine anion (I⁻), a bromine anion (Br⁻), or a chloride anion (Cl⁻).

In the present disclosure, a thickness of the photoactive layer may be preferably 100 nm to 1,000 nm and more preferably 300 nm to 600 nm.

The PSC provided by the present disclosure includes an ETL stacked on a surface of the photoactive layer. In the present disclosure, a material of the ETL may be preferably PC₆₁BM, and the ETL may have a thickness of preferably 30 nm.

The PSC provided by the present disclosure includes a CIL stacked on a surface of the ETL. In the present disclosure, a material of the CIL may be the polyoxomolybdate material with a structure of formula 1 described in the above technical solution; and a thickness of the CIL may be preferably 0.5 nm to 20 nm, more preferably 2 nm to 15 nm, and most preferably 4 nm.

The PSC provided by the present disclosure includes a cathode stacked on a surface of the CIL. In the present disclosure, the cathode may preferably be silver, copper, or gold; and a thickness of the cathode may be preferably 80 nm to 120 nm, more preferably 90 nm to 110 nm, and most preferably 100 nm.

In the present disclosure, a fabrication method of the PSC may preferably include the following steps:

an organic AIL material solution is coated on a surface of an anode to form an AIL on the surface of the anode;

an active layer solution is coated on a surface of the AIL, and an anti-solvent treatment and an annealing treatment arc conducted sequentially to form a photoactive layer on the surface of the AIL;

an organic ETL material solution is coated on a surface of the photoactive layer to form an ETL on the surface of the photoactive layer;

a CIL material solution is coated on a surface of the ETL to form a CIL on the surface of the ETL; and

a cathode is evaporated on a surface of the CIL to obtain the PSC.

In the present disclosure, an AIL material solution may be coated on a surface of an anode to form an AIL on the surface of the anode. In the present disclosure, the anode may be preferably attached to a substrate. In the present disclosure, the anode may be preferably evaporated on a surface of the substrate, such that the anode is attached to the substrate. The present disclosure has no special limitations on conditions of the evaporation, and evaporation conditions well known in the art may be adopted. In the present disclosure, a thickness of the anode evaporated corresponds to the thickness of the anode in the above technical solution.

In the present disclosure, a material of the AIL may preferably be NH₄-Mo₁₃₂ or PTAA. In the present disclosure, when the AIL material is NH₄-Mo₁₃₂, a solvent used for the organic AIL material solution may be preferably methanol; the AIL material solution may have a concentration of preferably 0.25 mg/mL, to 2 mg/mL and more preferably 1 mg/mL to 1.5 mg/mL; and a method for the coating may be preferably spin-coating, and the spin-coating may be conducted at a speed of preferably 1,900 r/min to 2,100 r/min and more preferably 2,000 r/min.

In the present disclosure, when the AIL material is PTAA, a solvent used for the organic AIL material solution may be preferably chlorobenzene; the organic AIL material solution may have a concentration of preferably 3.0 mg/mL; and a method for the coating may be preferably spin-coating, and the spin-coating may be conducted at a speed of preferably 5,000 r/min to 7,000 r/min and more preferably 6,000 r/min. The present disclosure has no specific limitations on a time of the coating, and the coating time can be adjusted according to a coating thickness. In the present disclosure, a coating thickness of the AIL material corresponds to the thickness of the AIL.

When the AIL material is PTAA, after the coating is completed, the present disclosure may preferably conduct an annealing treatment. In the present disclosure, the annealing treatment may be conducted at preferably 80° C. to 120° C. and more preferably 100° C. for preferably 10 min to 30 min. When the AIL material is NH₄-Mo₁₃₂, the present disclosure may preferably allow standing for 2 min to 5 min in a nitrogen glove box to make a solvent volatilized.

In the present disclosure, after the AIL is formed, an active layer solution may be coated on a surface of the AIL, and then an anti-solvent treatment and an annealing treatment may be conducted to form a photoactive layer on the surface of the AIL. The present disclosure has no special limitations on a type of the solvent used for the active layer solution, and according to a specific composition of the photoactive layer, a corresponding solvent well known in the art may be adopted. In the present disclosure, the active layer solution may have a concentration of preferably 1 M to 2 M and more preferably 1.4 M.

In the present disclosure, a method for the coating may be preferably spin-coating, and the spin-coating may be preferably conducted as follows: spin-coating at a rotational speed of 1,000 rpm for 10 s, and spin-coating at a rotational speed of 5,000 rpm for 30 s. The present disclosure has no specific limitations on a total time of the coating, and the coating time can be adjusted according to a coating thickness. In the present disclosure, a coating thickness of the active layer solution corresponds to the thickness of the photoactive layer.

In the present disclosure, after the coating is completed, a resulting material may be preferably subjected to an anti-solvent treatment and an annealing treatment sequentially to form a photoactive layer on the surface of the AIL. In the present disclosure, the anti-solvent treatment may be preferably conducted as follows: 5 s before the spin-coating of the active layer solution is completed, rapidly adding an anti-solvent to conduct the anti-solvent treatment; and the anti-solvent may preferably be chlorobenzene. The present disclosure has no special limitations on an amount of the anti-solvent, and the amount of the anti-solvent can be adjusted according to actual needs.

In the present disclosure, the annealing treatment may be conducted at preferably 80° C. to 120° C. and more preferably 100° C. for preferably 10 min to 30 min and more preferably 20 min to form a black active perovskite layer.

In the present disclosure, after the photoactive layer is formed, an organic ETL material solution may preferably be coated on a surface of the photoactive layer to form an ETL on the surface of the photoactive layer. In the present disclosure, a material of the ETL may be preferably PC₆₁BM, a solvent for the organic ETL material solution may be preferably chlorobenzene; and the organic ETL material solution may have a concentration of preferably 15 mg/mL to 25 mg/mL, and more preferably 20 mg/mL.

In the present disclosure, a method for the coating may be preferably spin-coating; and the spin-coating may be conducted at a speed of preferably 800 r/min to 2,000 r/min and more preferably 1,000 r/min, and the spin-coating may be conducted for preferably 30 s to 60 s and more preferably 40 s.

In the present disclosure, after the ETL is formed, a CIL material solution may be coated on a surface of the ETL to form a CIL on the surface of the ETL. In the present disclosure, a solvent used for the CIL material solution may be preferably an alcohol solution, and the alcohol solution may be preferably ethanol; and the CIL material solution may have a concentration of preferably 0.25 mg/mL to 2 mg/mL, more preferably 0.5 mg/mL to 1 mg/mL, and further more preferably 0.5 mg/mL.

In the present disclosure, a method for the coating may be preferably spin-coating, and the spin-coating may be conducted at a speed of preferably 2,000 r/min to 3,000 r/min and more preferably 3,000 r/min. The present disclosure has no specific limitations on a time of the coating, and the coating time can be adjusted according to a coating thickness.

In the present disclosure, after the CIL is formed, a cathode may be evaporated on a surface of the CM to obtain the PSC. The present disclosure has no special limitations on a method of the evaporation, and an evaporation method well known in the art may be adopted. In the present disclosure, the evaporation may be conducted preferably with silver, copper, or gold as a raw material; the evaporation may be conducted at a rate of preferably 0.5 Å/s to 1.5 Å/s, more preferably 0.7 Å/s to 1.3 Å/s, and most preferably 1 Å/s; the evaporation may be conducted under a vacuum degree of preferably (1.7-1.9)×10⁻⁴ Pa and more preferably 1.8×10⁻⁴ Pa; the evaporation may be conducted at a current of preferably 32 A to 40 A and more preferably 34 A to 37 A; and the evaporation may be conducted at a voltage of preferably 2 V to 4 V and more preferably 3.5 V to 4 V. The present disclosure has no special limitations on a form of the metal used for the evaporation, and commercially available silver, copper, and gold (powder, strip, sheet, or block) for evaporation well known in the art may be adopted.

The present disclosure provides an OLED, including an anode, an HTL, a light-emitting layer, an ETL, and a cathode that are stacked sequentially, where a material of the ETL is the polyoxomolybdate material according to the above technical solution or a polyoxomolybdate material prepared by the preparation method according to the above technical solution.

The OLED provided by the present disclosure includes an anode. In the present disclosure, the anode may preferably be ITO, and a thickness of the anode may be preferably 100 nm to 200 nm, more preferably 110 nm to 160 nm, and most preferably 135 nm.

In the present disclosure, the anode may be preferably attached to a substrate, and the substrate may be preferably a glass substrate. The present disclosure has no special limitations on a thickness of the substrate, and a thickness well known in the art may be adopted.

The OLED provided by the present disclosure includes an HTL stacked on a side surface of the anode. In the present disclosure, a material of the HTL may preferably be NH₄-Mo₁₃₂ or PEDOT:PSS. When the material or the HTL is PEDOT:PSS, a thickness of the HTL may be preferably 20 nm to 40 nm and more preferably 25 nm to 35 nm. When the material of the HTL is NH₄-Mo₁₃₂, a thickness of the HTL may be preferably 5 nm to 10 nm and more preferably 7 nm.

The OLED provided by the present disclosure includes a light-emitting layer stacked on a surface of the HTL. In the present disclosure, a material of the light-emitting layer may be preferably P-PPV, Super Yellow, or F8BT. The present disclosure has no special limitations on a source of the material of the light-emitting layer, and a commercially available product well known in the art may be adopted. In the present disclosure, a thickness of the light-emitting layer may be preferably 70 nm to 100 nm, more preferably 80 nm to 90 nm, and most preferably 85 nm.

In the present disclosure, structural formulas of materials in the light-emitting layer are as follows:

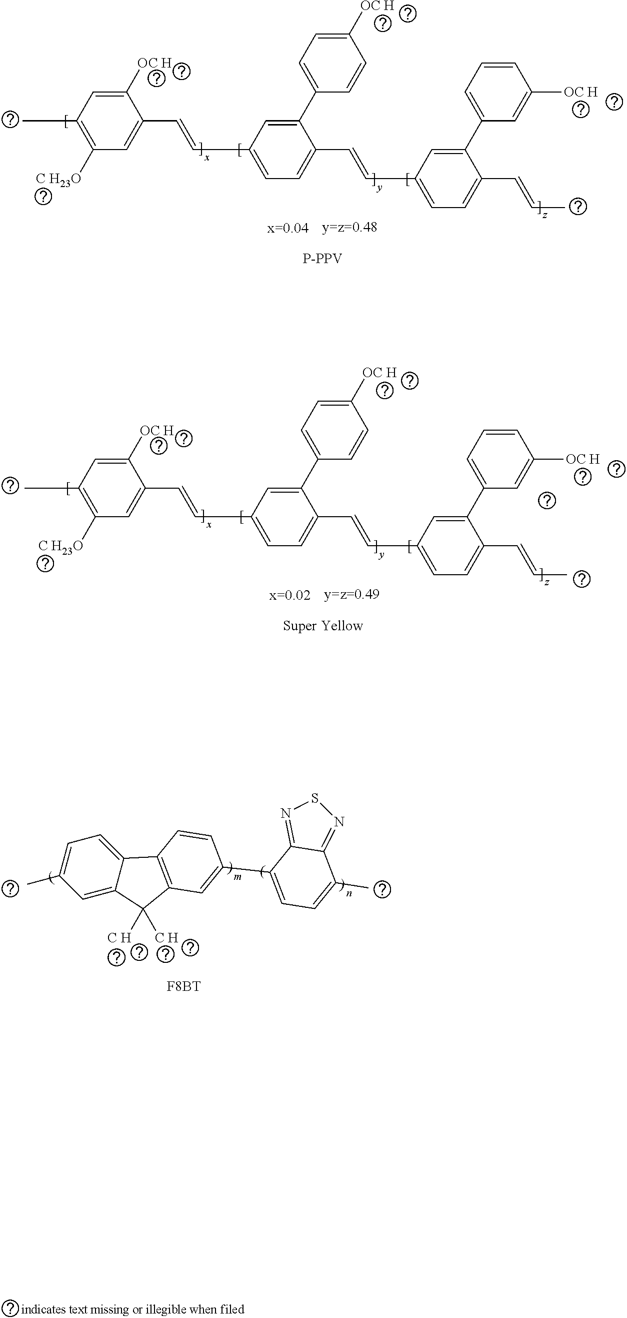

The OLED provided by the present disclosure includes an ETL stacked on a surface of the light-emitting layer. In the present disclosure, the material of the ETL may be the polyoxomolybdate material with a structure of formula 1 described in the above technical solution. In the present disclosure, a thickness of the ETL may be preferably 0.5 nm to 20 nm, more preferably 5 nm to 15 nm, and most preferably 4 nm.

The OLED provided by the present disclosure includes a cathode stacked on a surface of the ETL. In the present disclosure, the cathode may preferably be silver or aluminum; and a thickness of the cathode may be preferably 80 nm to 120 nm, more preferably 90 nm to 110 nm, and most preferably 100 nm.

In the present disclosure, a fabrication method of the OLED may preferably include the following steps:

an HTL material solution is coated on a surface of an anode to form an HTL on the surface of the anode;

a light-emitting layer solution is coated on a surface of the HTL, and a solvent is volatilized to form a light-emitting layer on the surface of the HTL;

an ETL material solution is coated on a surface of the light-emitting layer to form an ETL on the surface of the light-emitting layer; and

a metal cathode is evaporated on a surface of the ETL to obtain the OLED.

In the present disclosure, an HTL material solution may be coated on a surface of an anode to form an HTL on the surface of the anode. In the present disclosure, the anode may be preferably attached to a substrate. In the present disclosure, the anode may be preferably evaporated on a surface of the substrate, such that the anode is attached to the substrate. The present disclosure has no special limitations on conditions of the evaporation, and evaporation conditions well known in the art may be adopted. In the present disclosure, a thickness of the anode evaporation corresponds to the thickness of the anode in the above technical solution.

In the present disclosure, when the HTL material is NH₄-Mo₁₃₂, a solvent for the HTL material solution may be preferably methanol; and the HTL material solution may have a concentration of preferably 0.25 mg/mL to 2 mg/mL and more preferably 1 mg/mL to 1.25 mg/mL. In the present disclosure, a method for the coating may be preferably spin-coating, and the spin-coating may be conducted at a speed of preferably 1,900 r/min to 2,100 r/min and more preferably 2,000 r/min.

In the present disclosure, when the HTL material is PEDOT:PSS, the PEDOT:PSS may be preferably a PEDOT:PSS aqueous solution with model No. Clevios PVP Al 4083 purchased from Heraeus, Germany. In the present disclosure, the PEDOT:PSS aqueous solution may be preferably filtered through a 0.45 μm filter membrane before use; and a method for the coating may be preferably spin-coating, and the spin-coating may be conducted at a speed of preferably 3,000 r/min to 4,000 r/min and more preferably 3,500 r/min. The present disclosure has no specific limitations on a time of the coating, and the coating time can be adjusted according to a coating thickness. In the present disclosure, a coating thickness of the HTL material corresponds to the thickness of the HTL.

When the HTL material is PEDOT:PSS, after the coating is completed, the present disclosure may preferably conduct an annealing treatment. In the present disclosure, the annealing treatment may be conducted at preferably 80° C. to 120° C. and more preferably 110° C. for preferably 10 min to 30 min. The present disclosure utilizes the annealing treatment to remove moisture in a film, thereby facilitating the stability of the OLED. When the HTL material is NH₄-Mo₁₃₂, after the coating is completed, the present disclosure may preferably allow standing for 2 min to 5 min in a nitrogen glove box to make a solvent volatilized.

In the present disclosure, after the HTL is formed, a light-emitting layer solution may be coated on a surface of the HTL, and a solvent may be volatilized to form a light-emitting layer on the surface of the HTL. The present disclosure has no special limitations on a type of the solvent used for the light-emitting layer solution, and according to a specific composition of the light-emitting layer, a corresponding solvent well known in the art may be adopted.

In the present disclosure, the light-emitting layer solution may have a concentration of preferably 4 mg/mL to 10 mg/mL and more preferably 5 mg/mL to 6 mg/mL. In the present disclosure, a method for the coating may be preferably spin-coating, and the spin-coating may be conducted at a speed of preferably 800 r/min to 1500 r/min and more preferably 1000 r/min. The present disclosure has no specific limitations on a time of the coating, and the coating time can be adjusted according to a coating thickness. In the present disclosure, a coating thickness of the light-emitting layer solution corresponds to the thickness of the light-emitting layer.

In the present disclosure, the solvent may be volatilized preferably by subjecting a material obtained after the coating to a vacuum treatment for preferably 10 min to 60 min and more preferably 30 min.

In the present disclosure, after the light-emitting layer is formed, an ETL material solution may be coated on a surface of the light-emitting layer to form an ETL on the surface of the light-emitting layer. In the present disclosure, a solvent used for the ETL material solution may be preferably methanol; and the ETL material solution may have a concentration of preferably 0.25 mg/mL to 2 mg/mL, more preferably 0.5 mg/mL to 1 mg/mL, and further more preferably 0.5 mg/mL.

In the present disclosure, a method for the coating may be preferably spin-coating, and the spin-coating may be conducted at a speed of preferably 1,900 r/min to 2,100 r/min and more preferably 2,000 r/min. The present disclosure has no specific limitations on a time of the coating, and the coating time can be adjusted according to a coating thickness. In the present disclosure, a coating thickness of the ETL material solution corresponds to the thickness of the ETL.

In the present disclosure, after the ETL is formed, a metal cathode may be evaporated on a surface of the ETL to obtain the OLED. The present disclosure has no special limitations on a method of the evaporation, and an evaporation method well known in the art may be adopted. In the present disclosure, the evaporation may be conducted preferably with aluminum or silver as a raw material; the evaporation may be conducted at a rate of preferably 0.5 Å/s to 1.5 Å/s, more preferably 0.7 Å/s to 1.3 Å/s, and most preferably 1 Å/s; the evaporation may be conducted under a vacuum degree of preferably (1.7-1.9)×10⁻⁴ Pa and more preferably 1.8×10⁻⁴ Pa; the evaporation may be conducted at a current of preferably 32 A to 40 A and more preferably 34 A to 37 A; and the evaporation may be conducted at a voltage of preferably 2 V to 4 V and more preferably 3.5 V to 4 V. The present disclosure has no special limitations on a form of the metal, and commercially-available aluminum or silver (powder, strip, sheet, or block) for evaporation well known in the art may be adopted.

The technical solutions of the present disclosure will be clearly and completely described below with reference to the examples of the present disclosure. Apparently, the described examples are merely some rather than all of the examples of the present disclosure. All other examples obtained by a person of ordinary skill in the art based on the examples of the present disclosure without creative efforts shall fall within the protection scope of the present disclosure.

In the following examples, a preparation method of NH₄-Mo₁₃₂ is as follows:

N₂H₄ (H₂SO₄) (0.8 g, 4.5 mmol) is added to 250 mL of an aqueous solution with (NH₄)₆[Mo₇O₂₄](H₂O)₄ (5.6 g, 4.5 mmol) and CH₃COONH₄ (12.5 g, 162.2 mmol), a resulting mixed solution is stirred for 10 min such that the mixed solution turns blue-green, and then a CH₃COOH (83 mL, mass fraction: 50%) solution is added to obtain a green solution; the green solution is placed in a 500 mL open flask, and stirred at 20° C. in a fume hood such that the green solution slowly turns dark-brown; and 4 d later, a resulting red brown crystal is filtered out with glassware, rinsed with each of 90% ethanol and diethyl ether, and then air-dried to obtain the NH₄-Mo₁₃₂.

### Example 1

Preparation of (C₄)₁₅-Mo₁₃₂:

Compounds NH₄-Mo₁₃₂ and tetrabutylammonium bromide (TBAB) were taken in a charge molar ratio of 1:25, the NH₄-Mo₁₃₂ (100 mg) was dissolved in 10 mL of water to obtain a NH₄-Mo₁₃₂ solution, and TBAB (34 mg) was dissolved in 10 mL of water to obtain a TBAB solution; and the TBAB solution was added dropwise to the NH₄-Mo₁₃₂ solution, a resulting mixed solution was stirred at room temperature for 24 h and then filtered, and a resulting filter residue was rinsed 3 times with distilled water and vacuum-dried at 40° C. and 0.09 MPa for 12 h to obtain a polyoxomolybdate material, denoted as (C₄)₁₅-Mo₁₃₂.

### Example 2

Preparation of (C₆)₂₀-Mo₁₃₂:

Compounds NH₄-Mo₁₃₂ and tetrahexylammonium bromide (THAB) were taken in a charge molar ratio of 1:35, and then the NH₄-Mo₁₃₂ (200.7 mg) and THAB (131.3 mg) were each dissolved in 6 mL of H₂O to obtain a NH₄-Mo₁₃₂ aqueous solution and a THAB aqueous solution; the THAB aqueous solution was added dropwise to the NH₄-Mo₁₁₂ aqueous solution, a resulting mixed solution was stirred at room temperature for 24 h to obtain a dark-brown solution, and the dark-brown solution was subjected to ultrasonic vibration for 1 min and then filtered; and a resulting filter residue was rinsed 3 times with distilled water and vacuum-dried at 40° C. and 0.09 MPa for 12 h to obtain a polyoxomolybdate material, denoted as (C₆)₂₀-Mo₁₃₂.

### Example 3

Preparation of (C₆)₂₁-Mo₁₃₂:

Compounds NH₄-Mo₁₃₂ and THAB were taken in a charge molar ratio of 1:40, and then the NH₄-Mo₁₃₂ (200.7 mg) and THAB (149.6 mg) were each dissolved in 6 mL of H₂O to obtain a NH₄-Mo₁₃₂ aqueous solution and a THAB aqueous solution; the THAB aqueous solution was added dropwise to the NH₄-Mo₁₃₂ aqueous solution, a resulting mixed solution was stirred at room temperature for 24 h to obtain a dark-brown solution, and the dark-brown solution was subjected to ultrasonic vibration for 1 min and then filtered; and a resulting filter residue was rinsed 3 times with distilled water and vacuum-dried at 40° C. and 0.09 MPa for 12 h to obtain a polyoxomolybdate material, denoted as (C₆)₂₁-Mo₁₃₂.

### Example 4

Preparation of (C₈)₁₁-Mo₁₃₂:

Compounds NH₄-Mo₁₃₂ and tetraoctylammonium bromide (TOAB) were taken in a charge molar ratio of 1:20, the NH₄-Mo₁₃₂ (100 mg) was dissolved in 10 mL of a mixed solution of water and acetonitrile (a volume ratio of water to acetonitrile was 1:1) to obtain a NH₄-Mo₁₃₂ solution, and TOAB (40 mg) was dissolved in 10 mL of a mixed solution of water and acetonitrile (a volume ratio of water to acetonitrile was 1:1) to obtain a TOAB solution; and the TOAB solution was added dropwise to the NH₄-Mo₁₃₂ solution, a resulting mixed solution was stirred at room temperature for 24 h and then filtered, and a resulting filter residue was rinsed 3 times with distilled water and vacuum-dried at 40° C. and 0.09 MPa for 12 h to obtain a polyoxomolybdate material, denoted as (C₈)₁₁-Mo₁₃₂.

### Example 5

Preparation of (C₈)₁₉-Mo₁₃₂:

Compounds NH₄-Mo₁₃₂ and TOAB were taken in a charge molar ratio of 1:30, the NH₄-Mo₁₃₂ (200.3 mg) was dissolved in 6 mL of a mixed solution of water and acetonitrile (a volume ratio of water to acetonitrile was 1:4) to obtain a NH₄-Mo₁₃₂ solution, and TOAB (141.4 mg) was dissolved in 6 mL of a mixed solution of water and acetonitrile (a volume ratio of water to acetonitrile was 1:4) to obtain a TOAB solution; and the TOAB solution was added dropwise to the NH₄-Mo₁₃₂ solution, a resulting mixed solution was stirred at room temperature for 24 h and then filtered, and a resulting filter residue was rinsed 3 times with distilled water and vacuum-dried at 40° C. and 0.09 MPa for 12 h to obtain a polyoxomolybdate material, denoted as (C₈)₁₉-Mo₁₃₂.

### Example 6

Preparation of (C₈)₃₁-Mo₁₃₂:

Compounds NH₄-Mo₁₃₂ and TOAB were taken in a charge molar ratio of 1:42, the NH₄-Mo₁₃₂ (100 mg) was dissolved in 10 mL of a mixed solution of water and acetonitrile (a volume ratio of water to acetonitrile was 1:1) to obtain a NH₄-Mo₁₃₂ solution, and TOAB (80 mg) was dissolved in 10 mL of a mixed solution of water and acetonitrile (a volume ratio of water to acetonitrile was 1:1) to obtain a TOAB solution; and the TOAB solution was added dropwise to the NH₄-Mo₁₃₂ solution, a resulting mixed solution was stirred at room temperature for 24 h and then filtered, and a resulting filter residue was rinsed 3 times with distilled water and vacuum-dried at 40° C. and 0.09 MPa for 12 h to obtain a polyoxomolybdate material, denoted as (C₈)₃₁-Mo₁₃₂.

### Example 7

Preparation of (C₁₀)₂₀-Mo₁₃₂:

Compounds NH₄-Mo₁₃₂ and tetradecylammonium bromide (TDAB) were taken in a charge molar ratio of 1:30, the NH₄-Mo₁₃₂ (100 mg) was dissolved in 10 mL of a mixed solution of water and acetonitrile (a volume ratio of water to acetonitrile was 1:4) to obtain a NH₄-Mo₁₃₂ solution, and TDAB (85 mg) was dissolved in 10 mL of a mixed solution of water and acetonitrile (a volume ratio of water to acetonitrile was 1:4) to obtain a TDAB solution; and the TDAB solution was added dropwise to the NH₄-Mo₁₃₂ solution, a resulting mixed solution was stirred at room temperature for 24 h and then filtered, and a resulting filter residue was rinsed 3 times with distilled water and vacuum-dried at 40° C. and 0.09 MPa for 12 h to obtain a polyoxomolybdate material, denoted as (C₁₀)₂₀-Mo₁₃₂.

### Application Example 1

Fabrication of an ITO/PEDOT:PSS/PM6:Y6/(C₈)₃₁-Mo₁₃₂/Al OSC:

The CIL material prepared in Example 6 was used to fabricate a CIL.

A glass substrate coated with a 135 nm ITO anode was subjected to a UV-ozone treatment, then a PEDOT:PSS aqueous solution was filtered through a 0.45 μm filter membrane and then spin-coated on the ITO anode at 3,500 r/min with a coating thickness of 35 nm, and a resulting material was annealed at 110° C. for 30 min and then immediately transferred to a glove box to form an AIL; a PM6:Y6 active layer solution (a mass ratio of PM6 to Y6 was 1:1.2, a total concentration was 16 mg/mL, a solvent was chloroform, an additive was chloronaphthalene, and a volume ratio of the solvent to the chloronaphthalene was 995:5) was spin-coated on the PEDOT:PSS AIL at 2,500 r/min, and a resulting material was annealed on a hot plate at 70° C. for 10 min to form an active layer with a thickness of 100 nm; a (C₈)₃₁-Mo₁₃₂ methanol solution with a concentration of 0.5 mg/mL was spin-coated at 2,000 r/min for 40 s to form a CIL with a thickness of 4 nm; and a resulting material was placed in an evaporation chamber, and a Al cathode was evaporated at a speed of 1.0 Å/s, a vacuum degree of 1.8×10⁻⁴ Pa, a current of 36 A, and a voltage of 3.4 V such that a cathode with a thickness of 100 nm was formed to obtain the OSC.

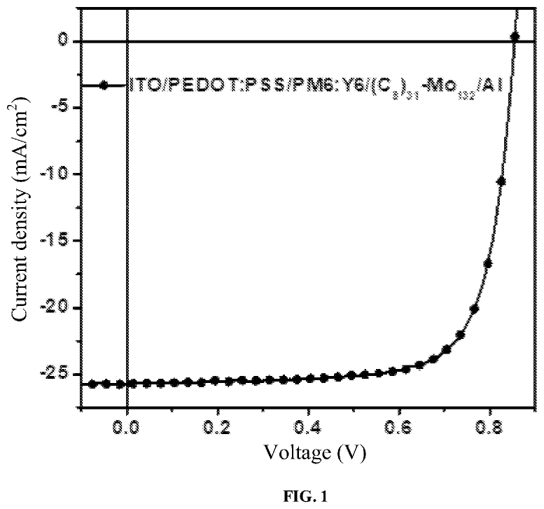

A current density-voltage performance test was conducted for the OSC obtained in this application example under simulated AM 1.5 G sunlight (100 mW/cm²), and a result was shown in FIG. 1. It can be seen from FIG. 1 that the OSC has an open-circuit voltage of 0.850 V, a short-circuit current density of 25.73 mA cm⁻², a filling factor of 0.747, and a calculated photoelectric conversion efficiency of 16.34%.

### Application Example 2

Fabrication of an ITO/NH₄-Mo₁₃₂/PM6:Y6/(C₈)₃₁-Mo₁₃₂/Al OSC:

NH₄-Mo₁₃₂ was adopted as an AIL material, and the material prepared in Example 6 was adopted as a CIL material.

A glass substrate coated with a 135 nm ITO anode was subjected to a UV-ozone treatment for 30 min, then a 1.25 mg/mL NH₄-Mo₁₃₂ methanol solution was spin-coated on the ITO anode at 2,000 r/min with a coating thickness of 10 nm, and the solvent was volatilized to form an AIL; a PM6:Y6 active layer solution (a mass ratio of PM6 to Y6 was 1:1.2, a total concentration was 16 mg/mL, a solvent was chloroform, an additive was chloronaphthalene, and a volume ratio of the chloroform to the chloronaphthalene was 995:5) was spin-coated on a surface of the NH₄-Mo₁₃₂ AIL, and a resulting material was annealed on a hot plate at 70° C. for 10 min to form an active layer with a thickness of 100 nm; a (C₈)₃₁-Mo₁₃₂ methanol solution with a concentration of 0.5 mg/mL was spin-coated at 2,000 r/min for 40 s to form a CIL with a thickness of 4 nm; and a resulting material was placed in an evaporation chamber, and a Al cathode was evaporated at a speed of 1.0 Å/s, a vacuum degree of 1.8×10⁻⁴ Pa, a current of 36 A, and a voltage of 3.4 V such that a cathode with a thickness of 100 nm was formed to obtain the OSC.

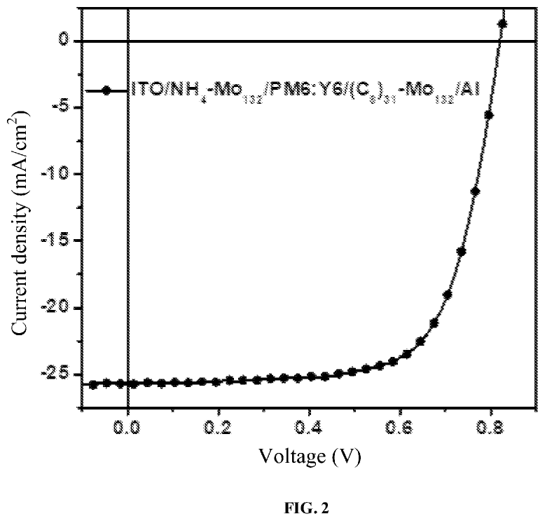

A current density-voltage performance test was conducted for the OSC fabricated in this application example under simulated AM 1.5 G sunlight (100 mW/cm²), and a result was shown in FIG. 2. It can be seen from FIG. 2 that the OSC has an open-circuit voltage of 0.815 V, a short-circuit current density of 25.69 mA cm⁻², a filling factor of 0.695, and a calculated photoelectric conversion efficiency of 14.55%.

### Application Example 3

Fabrication of an ITO/PTAA/Perovskite/PC₆₁BM/(C₈)₁₉-Mo₁₃₂/Al perovskite solar cell:

The (C₈)₁₉-Mo₁₃₂ prepared in Example 5 was adopted as a CIL material.

A glass substrate was coated with a 135 nm ITO anode, a 3.0 mg/mL PTAA chlorobenzene solution was spin-coated on the anode at 6,000 rpm for 30 s, and a resulting material was annealed on a hot plate at 100° C. for 10 min to form a PTAA AIL with a thickness of 10 nm; a perovskite precursor solution (1.4 M Cs_{0.05}FA_{0.8}MA_{0.15}PbI_{2.7}Br_{0.3} solution, and a solvent was a mixture of DMF and DMSO in a volume ratio of 4:1) was spin-coated on a surface of the PTAA AIL first at a low speed of 1,000 rpm for 10 s and then at a high speed of 5,000 rpm for 30 s, 300 μL of chlorobenzene was rapidly added dropwise for an anti-solvent treatment 5 s before the spin-coating was completed, and a resulting material was immediately baked on a hot plate at 100° C. for 20 min to form a black perovskite active layer with a thickness of 500 nm; then a 20 mg/mL PC₆₁BM chlorobenzene solution was spin-coated on a surface of the perovskite active layer at 1,000 rpm for 40 s to form an ETL with a thickness of 30 nm; a solution of 0.5 mg/mL CIL material (C₈)₁₉-Mo₁₃₂ in ethanol was spin-coated at 3,000 rpm for 40 s to obtain a CIL with a thickness of 4 nm; and a resulting material was placed in an evaporation chamber, and a Ag cathode was evaporated at a speed of 0.5 Å/s, a vacuum degree of 1.8×10⁻⁴ Pa, a current of 36 A, and a voltage of 3.4 V such that a cathode with a thickness of 100 nm was formed to obtain the perovskite solar cell.

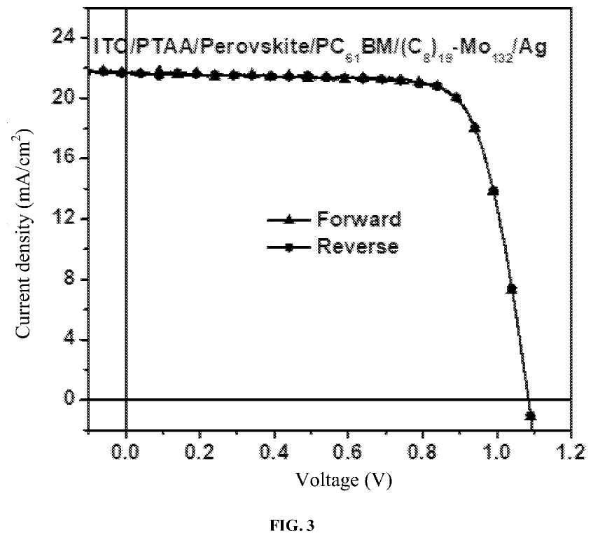

A current density-voltage performance test was conducted for the perovskite solar cell fabricated in this application example under simulated AM 1.5 G sunlight (100 mW/cm²), and a result was shown in FIG. 3. It can be seen from FIG. 3 that the OSC has an open-circuit voltage of 1.085 V, a short-circuit current density of 21.75 mA cm⁻², a filling factor of 0.757, and a calculated photoelectric conversion efficiency of 17.84%.

### Application Example 4

Fabrication of an ITO/PEDOT:PSS/Super Yellow/(C₈)₃₁-Mo₁₃₂/Al OLED:

The (C₈)₃₁-Mo₁₃₂ prepared in Example 6 was adopted as a CIL material.

A glass substrate coated with a 160 nm ITO anode was subjected to a UV-ozone treatment, then a PEDOT:PSS aqueous solution was filtered through a 0.45 μm filter membrane and then spin-coated on the ITO anode at 3,500 r/min with a coating thickness of 35 nm, and a resulting material was annealed at 110° C. for 30 min and then immediately transferred to a glove box to form an HTL; a Super Yellow solution (a total concentration was 6 mg/mL and a solvent was toluene) was spin-coated on the PEDOT:PSS HTL at 1,000 r/min, and a resulting material was subjected to a vacuum treatment for 30 min to form a light-emitting layer with a thickness of 85 nm; a (C₈)₃₁-Mo₁₃₂ methanol solution with a concentration of 0.5 mg/mL was spin-coated at 2,000 r/min for 40 s to form an ETL with a thickness of 4 nm; and a resulting material was placed in an evaporation chamber, and a Al cathode was evaporated at a speed of 1.0 Å/s, a vacuum degree of 1.8×10⁻⁴ Pa, a current of 36 A, and a voltage of 3.4 V such that a cathode with a thickness of 100 nm was formed to obtain the OLED.

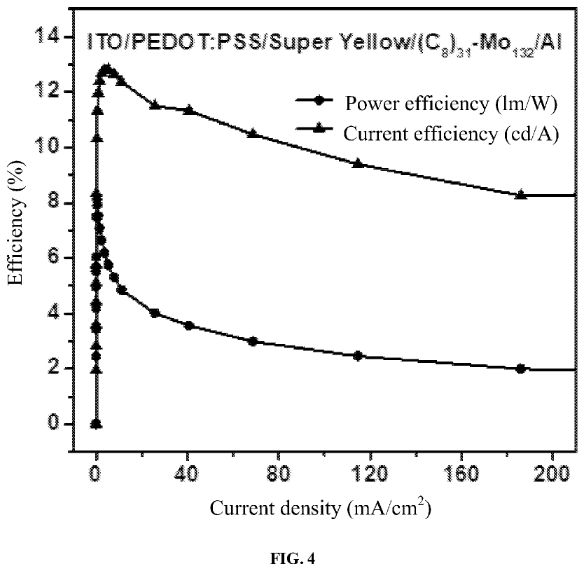

An efficiency-current density performance test was conducted for the OLED fabricated in this application example in a dark state, and a result was shown in FIG. 4. It can be seen from FIG. 4 that the OLED has a turn-on voltage of 2.7 V, a maximum brightness of 26,630 cd/m², a current efficiency of 12.82 cd/A, and a power efficiency of 8.11 lm/W, indicating that the OLED has prominent diode performance.

### Application Example 5

Fabrication of an ITO/NH₄-Mo₁₃₂/Super Yellow/(C₈)₃₁-Mo₁₃₂/Al OLED:

NH₄-Mo₁₃₂ was adopted as an HTL material, and the (C₈)₃₁-Mo₁₃₂ prepared in Example 6 was adopted as an ETL material.

A glass substrate coated with a 160 nm ITO anode was subjected to a UV-ozone treatment for 30 min, then a 1.25 mg/mL NH₄-Mo₁₃₂ methanol solution was spin-coated on the ITO anode at 2,000 r/min with a coating thickness of 10 nm to form an HTL; a Super Yellow solution (a total concentration was 6 mg/mL and a solvent was toluene) was spin-coated on a surface of the NH₄-Mo₁₃₂ HTL at 1,000 r/min with a coating thickness of 85 nm, and a resulting material was subjected to a vacuum treatment for 30 min to form a light-emitting layer with a thickness of 85 nm; a (C₈)₃₁-Mo₁₃₂ methanol solution with a concentration of 0.5 mg/mL was spin-coated at 2,000 r/min for 40 s to form an ETL with a thickness of 4 nm; and a resulting material was placed in an evaporation chamber, and a Al cathode was evaporated at a speed of 1.0 Å/s, a vacuum degree of 1.8×10⁻⁴ Pa, a current of 36 A, and a voltage of 3.4 V such that a cathode with a thickness of 100 nm was formed to obtain the OLED.

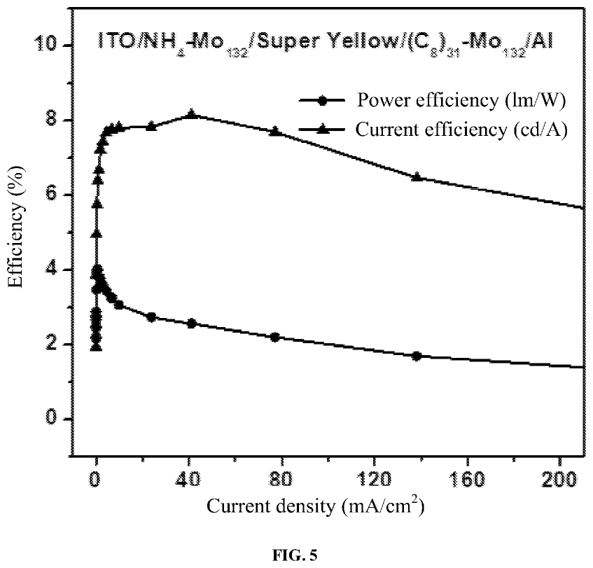

An efficiency-current density performance test was conducted for the OLED fabricated in this application example in a dark state, and a result was shown in FIG. 5. It can be seen from FIG. 5 that the OLED has a turn-on voltage of 3.1 V, a maximum brightness of 20,620 cd/m², a current efficiency of 8.15 cd/A, and a power efficiency of 4.02 lm/W, indicating that the OLED has prominent diode performance.

The above descriptions are merely preferred implementations of the present disclosure. It should be noted that a person of ordinary skill in the art may further make several improvements and modifications without departing from the principle of the present disclosure, but such improvements and modifications should be deemed as falling within the protection scope of the present disclosure.

What is claimed is:

1. A polyoxomolybdate material, with a composition shown in formula 1:
((CₙH₂ₙ₊₁)₄N)ₓ(NH₄)_{y}[Mo₇₂^{VI}Mo₆₀^{V}O₃₇₂(CH₃COO)₃₀(H₂O)₇₂] formula 1,
wherein n=4 to 12; x and y are each independently 1 to 42; and x+y≤42, x≠0, and y≠42.

2. The polyoxomolybdate material according to claim 1, wherein n=4, 6, 8, 10, or 12.

3. A preparation method of the polyoxomolybdate material according to claim 1, comprising the following steps:
mixing a NH₄-Mo₁₃₂ solution and an alkylammonium bromide solution, and obtaining the polyoxomolybdate material by an exchange reaction,
wherein the NH₄-Mo₁₃₂ has a structure shown in formula 2:
(NH₄)₄₂[Mo₇₂^{VI}Mo₆₀^{V}O₃₇₂(CH₃COO)₃₀(H₂O)₇₂](H₂O)₃₀₀(CH₃COONH₄)₁₀ formula 2; and
the alkylammonium bromide in the alkylammonium bromide solution has a structural formula of (CₙH₂ₙ₊₁)₄NBr, wherein n=4 to 12.

4. The preparation method according to claim 3, wherein n=4, 6, 8, 1 0, or 12.

5. The preparation method according to claim 3, wherein a charge molar ratio of the NH₄-Mo₁₃₂ in the NH₄-Mo₁₃₂ solution to the alkylammonium bromide in the alkylammonium bromide solution is 1:(1-42).

6. The preparation method according to claim 4, wherein a charge molar ratio of the NH₄-Mo₁₃₂ in the NH₄-Mo₁₃₂ solution to the alkylammonium bromide in the alkylammonium bromide solution is 1:(1-42).

7. The preparation method according to claim 3, wherein the exchange reaction is conducted at room temperature for 12 h to 24 h.

8. The preparation method according to claim 4, wherein the exchange reaction is conducted at room temperature for 12 h to 24 h.

9. Use of the polyoxomolybdate material according to claim 1 as a cathode interfacial layer (CIL) material in a field of optoelectronic devices.

10. Use of the polyoxomolybdate material according to claim 9, wherein n=4, 6, 8, 10, or 12.
